(19) United States
(12) Patent Application Publication
(10) Pub. No.: US 2006/0138509 A1
(43) Pub. Date: Jun. 29, 2006

(54) Magnetic random access memory with lower switching field through indirect exchange coupling

(75) Inventors: Yuan-Jen Lee, Hsinchu (TW); Yung-Hung Wang, Hsinchu (TW); Lien-Chang Wang, Hsinchu (TW); Ming-Jer Kao, Hsinchu (TW)

Correspondence Address: BIRCH STEWART KOLASCH & BIRCH, PO BOX 747, FALLS CHURCH, VA, 22040-0747, US

(73) Assignee: INDUSTRIAL TECHNOLOGY RESEARCH INSTITUTE

(21) Appl. No.: 11/155,465

(22) Filed: Jun. 20, 2005

(30) Foreign Application Priority Data
Dec. 29, 2004 (TW) 93141242

(51) Int. Cl. H01L 27/108

(52) U.S. Cl. 257/296

(57) ABSTRACT

A magnetic random access memory with lower switching field through indirect exchange coupling. The memory includes a first antiferromagnetic layer, a pinned layer formed on the first antiferromagnetic layer, a tunnel barrier layer formed on the pinned layer, a ferromagnetic free layer formed on the tunnel barrier layer, a metal layer formed on the ferromagnetic free layer, and a second antiferromagnetic layer formed on the metal layer. The anisotropy axis of the second antiferromagnetic layer and the ferromagnetic layer and that of the ferromagnetic free layer are arranged in parallel. The net magnetic moment of the antiferromagnetic layer interface between the second antiferromagnetic layer and the metal layer is close to zero. The memory has the advantages of lowering the switching field of the ferromagnetic layer and lowering the writing current.

This application claims the benefit of Taiwan Patent Application No. 9,314,1242, filed on Dec. 29, 2004, which is hereby incorporated by reference for all purposes as if fully set forth herein.

### BACKGROUND

1. Field of Invention

The invention relates to a magnetic random access memory, and in particular to a magnetic random access memory that has a lower switching field in the ferromagnetic free layer and power consumption.

2. Related Art

The magnetic random access memory (MRAM) is a type of nonvolatile memory. It utilizes magnetoresistance properties to record information and has the advantages of non-volatility, high density, high read/write speed, and anti-radiation. When writing data, a general method is to use the intersection of the induced magnetic fields of two circuit lines, the bit line and the write word line, to select a cell. Resistance is modified by changing the magnetization of a ferromagnetic free layer. When the MRAM reads recorded data, a current is supplied to the selected magnetic memory cell to read its resistance, thereby determining the corresponding digital value.

The magnetic memory cell between the bit line and the write word line is a stacked structure of a multi-layered metal material. It consists of a stack of a soft ferromagnetic layer, a tunnel barrier layer, a hard ferromagnetic layer, an antiferromagnetic layer, and a nonmagnetic conductor. Controlling the magnetizations of the upper and lower layers of the tunnel barrier layer to be parallel or anti-parallel determines whether the memory state is “0” or “1.”

As the magnetic memory is designed to have a high density, the size of the memory cell should be decreased. This requires an increase in the magnetic field for switching the ferromagnetic free layer, increasing the provided current. The large current makes the circuit design or the driver circuit design more difficult.

To solve the large current problem, most techniques adopt the means of changing magnetic memory cells so that their shape is closer to a circle. Although this method can reduce the switching field of the ferromagnetic free layer, the switching behavior of the magnetization of the ferromagnetic free layer becomes very complicated.

U.S. Pat. No. 6,728,132 discloses another solution. It primarily solves the discontinuous switching behavior of the magnetization of the ferromagnetic free layer. The ferromagnetic free layer is covered by a non-magnetic metal layer and a ferromagnetic layer. By adjusting the thickness of the metal layer, the magnetization of the ferromagnetic free layer and the covering ferromagnetic layer are anti-parallel to each other, forming closed magnetic lines. However, it has a limited effect in terms of lowering the switching field of the ferromagnetic free layer.

As the capacity and density of memory both become larger, the write-in current needed by the magnetic memory also increases due to the structure of the magnetic memory cells. This imposes some difficulty in circuit designs. Therefore, it is necessary to provide a novel magnetic memory cell structure with a lower write-in current.

### SUMMARY

Accordingly, the invention relates to a magnetic random access memory with lower switching field through indirect exchange coupling that substantially obviates one or more of the abovementioned problems in the related art.

According to object of the invention, the magnetic random access memory with lower switching field through indirect exchange coupling may reduce the switching field of the ferromagnet free layer.

According to the embodiment of the invention, the magnetic random access memory with lower switching field through indirect exchange coupling may reduce write current when writing data into the memory cell.

Additional features and advantages of the magnetic random access memory with lower switching field through indirect exchange coupling of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the invention, as embodied and broadly described, a magnetic random access memory with lower switching field through indirect exchange coupling may, for example, include a first antiferromagnetic layer; a pinned layer formed on the first antiferromagnetic layer; a tunnel barrier layer formed on the pinned layer; a ferromagnetic free layer formed on the tunnel barrier layer; a metal layer formed on the ferromagnetic free layer; and a second antiferromagnetic layer formed on the metal layer.

According to the embodiment of the invention, the anisotropy axis of the second antiferromagnetic layer and that of the ferromagnetic free layer are arranged in parallel.

According to the embodiment of the invention, the net moment of the interface between the second antiferromagnet layer and the ferromagnet free layer is nearly zero.

According to the embodiment of the invention, the magnetic random access memory with lower switching field through indirect exchange coupling has the advantage of reducing the switching field of the ferromagnetic free layer.

According to the embodiment of the invention, the magnetic random access memory with lower switching field through indirect exchange coupling has the advantage of reducing write current.

According to the embodiment of the invention, few modifications are made in the manufacturing process for the magnetic random access memory with lower switching field. Thus, the manufacturing process may integrate with the original process for the magnetic random access memory, and the switching field is effectively reduced.

In the following description, for purposes of explanation numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

### BRIEF DESCRIPTION OF THE DRAWINGS

The above and other objects, features and other advantages of the invention will be more clearly understood from the following detailed description when taken in conjunction with the accompanying drawings, in which:

FIG. 1 shows the MRAM of the invention;

FIG. 2 is a schematic view of the anisotropy axis of the disclosed MRAM; and

FIG. 3 shows experimental results of the coercivity of the disclosed MRAM.

### DETAILED DESCRIPTION

Reference will now be made in greater detail to a preferred embodiment of the invention, an example of which is illustrated in the accompanying drawings. Wherever possible, the same reference numerals are used throughout the drawings and the description to refer to the same or like parts. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

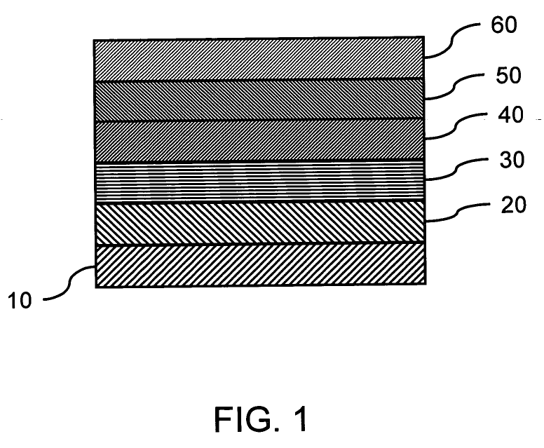

FIG. 1 shows the simplified cross-sectional view of a typical MRAM. The drawing also shows a single MRAM (or memory cell). The actual MRAM array can be composed of several MRAM's shown in FIG. 1.

The magnetic memory includes a first antiferromagnetic layer 10, a pinned layer 20 formed on the first antiferromagnetic layer 10, a tunnel barrier layer 30 formed on the pinned layer 20, a ferromagnetic free layer 40 formed on the tunnel barrier layer 30, a metal layer 50 formed on the ferromagnetic free layer 40, and a second antiferromagnetic layer 60 formed on the metal layer 50.

The first antiferromagnet layer 10 is made from antiferromagnetic material, for example PtMn or IrMn.

The pinned layer 20 formed on the first antiferromagnetic layer 10 may utilize a ferromagnetic material with at least one layer or an artificial antiferromagnetic layer with three layers. Ferromagnetic material, nonmagnetic metal and ferromagnetic material are stacked sequentially to form the artificial antiferromagnetic layer, in which the magnetization of the two ferromagnetic layers are anti-parallel. For example, the material may be CoFe/Ru/CoFe or CoFe/Cu/CoFe.

The material of the tunnel barrier layer 30 formed on the pinned layer 20 may be AlOx or MgO.

The ferromagnetic free layer 40 formed on the tunnel barrier layer 30 may utilize a ferromagnetic material with at least one layer or an artificial antiferromagnetic layer with three layers. The ferromagnetic layer may use NiFe, CoFe, or CoFeB, while the artificial antiferromagnetic layer may use CoFe/Ru/CoFe or CoFeB/Cu/CoFeB. The magnetization of the ferromagnetic free layer 40 may change freely.

The metal layer 50 is made from nonmagnetic conductive material, e.g. Cu, Ru, or Ag. The second antiferromagnetic layer 60 is made from antiferromagnetic metal material, e.g. RtMn, IrMn, or CoO.

According to the principle of the invention, the magnetic direction of the easy axisanisotropy of the second antiferromagnetic layer 60 and that of the ferromagnetic free layer 40 are arranged in parallel. The net magnetic moment on the antiferromagnetic layer interface between the second antiferromagnetic layer 60 and the metal layer 50 is nearly zero. The interface is a compensated interface.

The material of the components listed hereinafter is only for illustration. It is known to those skilled in the art that other materials that have the same function and technical effects may be employed on the structure in accordance with the invention.

In this embodiment, the compositions of the first antiferromagnetic layer 10, the pinned layer 20, the tunnel barrier layer 30 and the ferromagnetic free layer 40 in accordance with the invention are similar with that of the prior art.

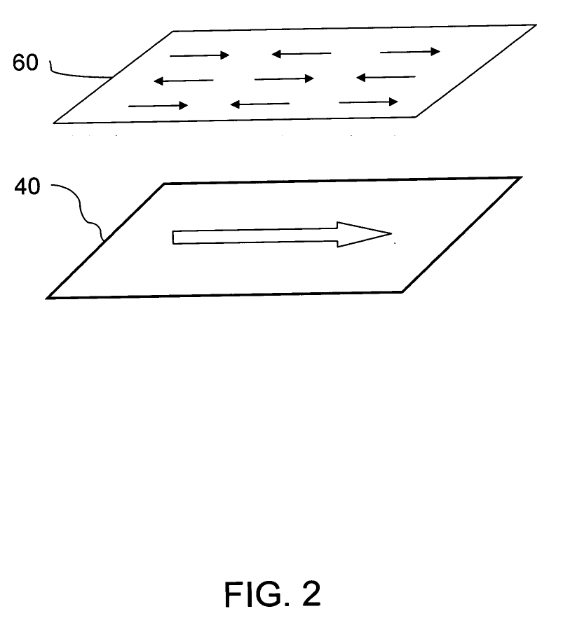

Refer to FIG. 2 illustrating the schematic view of the easy axis of the MRAM in accordance with the invention, in which the shape and thickness of each layer are only for illustration and are not intended to limit the implementation of the invention. As shown in the figure, the anisotropy axis of the second antiferromagnetic layer 60 and that of the ferromagnetic free layer 40 are arranged in parallel.

The MRAM of the invention may be manufactured with the general process. The first antiferromagnetic layer 10 is first formed, and then the pinned layer 20 is formed on the first antiferromagnetic layer 10. The tunnel barrier layer 30 is then formed on the pinned layer 20.

The ferromagnetic free layer 40 is then formed on the tunnel barrier layer 30, followed by forming the metal layer 50. Finally, the second antiferromagnetic layer 60 is formed on the metal layer 60. The materials have been mentioned above.

The anisotropy axis of the second antiferromagnetic layer 60 and that of the ferromagnetic free layer 40 are arranged in parallel such that the net magnetic moment of the antiferromagnetic layer interface between the second antiferromagnetic layer 60 and the metal layer 50 is nearly zero during the manufacturing process.

The principle of the invention is given in detail as follows. The ferromagnetic free layer 40 is formed from ferromagnetic material with at least one layer. The anisotropy axis of the second antiferromagnetic layer 60 and that of the ferromagnetic free layer 40 are arranged in parallel, as illustrated in FIG, 2. The thickness of the metal layer 50 is adjustable such that an energy term occurs in the equation indicating the ferromagnetic free layer 40 through indirect exchange coupling between layers. The energy term is represented as equation (1):
E=−J sin² θ (1)

The value of J is always larger than zero. θis the angle between the magnetization of the ferromagnetic layer 40 and the anisotropy axis. The applied field needed to switch the magnetization of the ferromagnetic layer 40 is reduced by inducing this energy term. Furthermore, the write current is also reduced.

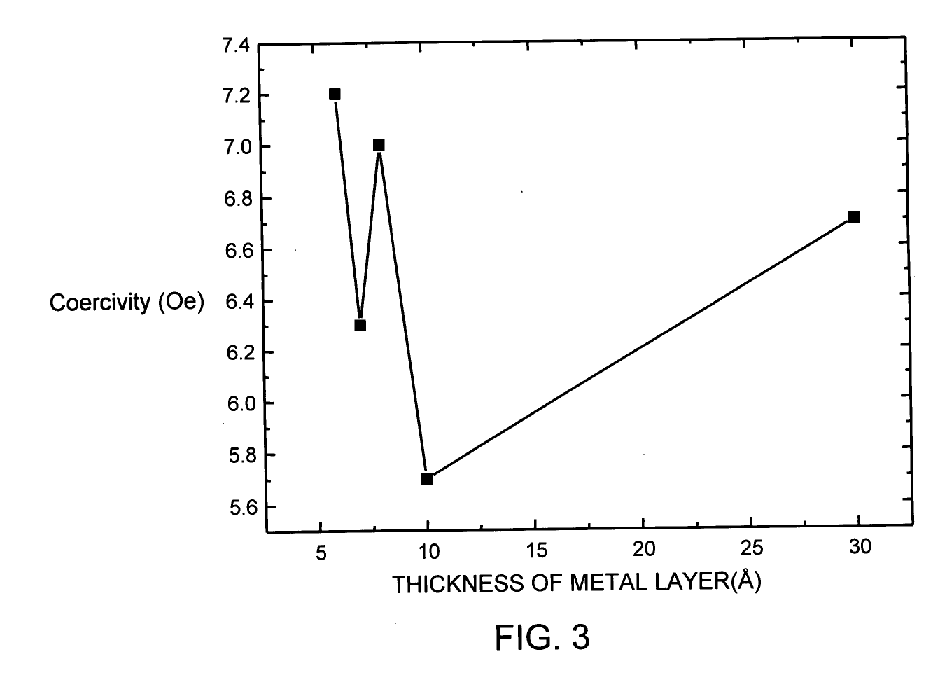

The experimental results of the disclosed MRAM are illustrated in FIG. 3, in which the ferromagnetic free layer 40 employs CoFe with a thickness of 2.5 nm. The metal layer employs Ru, while the second antiferromagnet layer 60 employs PtMn with a thickness of 15 nm. The metal layer 50 with different thickness is adopted for testing. As shown in FIG. 3, by adjusting the thickness of the metal layer 50, the coercivity of the ferromagnet free layer changes with the thickness of the metal layer 50

It can be seen in FIG. 3 that the coercivity is reduced according to the embodiment of the invention. Particularly, in case of the net magnetic moment of the antiferromagnetic layer interface between the second antiferromagnetic layer 60 and the metal layer 50 being nearly zero, the coercivity is reduced more than that of the metal layer with the same thickness.

The magnetic random access memory with lower switching field has the advantage of reducing the switching field of the ferromagnetic free layer 40, and the write current is also reduced.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A magnetic random access memory with lower switching field through indirect exchange coupling, comprising:
a magnetic memory cell with at least one ferromagnetic free layer;
a metal layer formed on the ferromagnetic free layer; and
an antiferromagnetic layer formed on the metal layer.

2. The MRAM of claim 1, wherein the anisotropy axis of the antiferromagnetic layer and that of the ferromagnetic free layer are arranged parallel.

3. The MRAM of claim 1, wherein the net magnetic moment of the antiferromagnetic layer interface between the antiferromagnetic layer and the metal layer is nearly zero.

4. The MRAM of claim 1, wherein the metal layer is made from nonmagnetic conductive layer

5. The MRAM of claim 1, wherein the antiferromagnetic layer is made from antiferromagnetic material.

6. A magnetic random access memory with lower switching field through indirect exchange coupling, comprising:
a first antiferromagnetic layer;
a pinned layer formed on the first antiferromagnetic layer;
a tunnel barrier layer formed on the pinned layer;
a ferromagnetic free layer formed on the tunnel barrier layer;
a metal layer formed on the ferromagnetic free layer; and
a second antiferromagnetic layer formed on the metal layer.

7. The MRAM of claim 6, wherein the anisotropy axis of the second antiferromagnetic layer and that of the ferromagnetic free layer are arranged parallel.

8. The MRAM of claim 6, wherein the net magnetic moment of the ferromagnetic layer interface between the second antiferromagnetic layer and the metal layer is nearly zero.

9. The MRAM of claim 6, wherein the metal layer is made from nonmagnetic conductive material.

10. The MRAM of claim 6, wherein the second antiferromagnetic layer is made from antiferromagnetic metal material.
